(19) United States
(12) Patent Application Publication
(10) Pub. No.: US 2024/0077588 A1
(43) Pub. Date: Mar. 7, 2024

(54) OPTICAL SENSOR

(71) Applicant: Sharp Semiconductor Innovation Corporation, Tenri City (JP)

(72) Inventors: Takayuki SHIMIZU, Tenri City (JP); Takahiro INOUE, Tenri City (JP); Kohji HAMAGUCHI, Tenri City (JP); Takuma HIRAMATSU, Tenri City (JP); KAZUO NODA, Tenri City (JP)

(21) Appl. No.: 18/234,436

(22) Filed: Aug. 16, 2023

(30) Foreign Application Priority Data
Sep. 2, 2022 (JP) 2022-140364

(51) Int. Cl. G01S 7/481; G01S 17/08

(52) U.S. Cl. CPC G01S 7/4816; G01S 17/08

(57) ABSTRACT

An optical sensor includes a light-emitting element configured to project light that changes with time; a light-receiving element including a pn junction and configured to directly or indirectly receive the light projected by the light-emitting element; a measuring section configured to measure an electric current generated based on an amount of the light received by the light-receiving element; and a bias application section configured to apply a bias to the light-receiving element, wherein the bias application section, before measuring the electric current generated based on the amount of the light received, applies the bias to the light-receiving element to cause either a forward current that flows when the light-receiving element is turned ON or a breakdown current that flows when the pn junction breaks down to flow through the pn junction.

### CROSS-REFERENCE TO RELATED APPLICATION

The present application claims priority from Japanese Application JP 2022-140364, the content of which is hereby incorporated by reference into this application.

### BACKGROUND OF THE INVENTION

### Field of the Invention

The present invention relates to optical sensors.

### Description of the Related Art

Proximity sensors are known as a type of optical sensor for measuring a distance to a detection target. The proximity sensor projects light emitted by an LED onto a detection target and receives light reflected off the detection target by a photodiode, to detect the detection target and measure a distance to the detection target in accordance with the intensity of the received light.

Japanese Unexamined Patent Application Publication, Tokukai, No. 2000-329616 discloses an image sensor using a photodiode as a photoelectric conversion element. In the structure of Japanese Unexamined Patent Application Publication, Tokukai, No. 2000-329616, when the quantity of incident light to the photodiode decreases, the resistance value of an MOS transistor for converting the sensor current in the photodiode to voltage increases, and as a result, the junction capacitance of the photodiode discharges the electric charge stored therein to prevent an afterimage from being observed over an extended period of time.

### Problems to be Solved by the Invention

As described above, proximity sensors are known using a photodiode. However, the proximity sensor could in some cases take more time to be ready for stable measurement in a dark environment than in a bright environment. Meanwhile, in Japanese Unexamined Patent Application Publication, Tokukai, No. 2000-329616, the resistance value of an MOS transistor differs when the sensor current is large and when the sensor current is small, and the observable time of the afterimage due to a different time constant from the junction capacitance of the photodiode poses an issue. Therefore, the structure of Japanese Unexamined Patent Application Publication, Tokukai, No. 2000-329616 is still short of addressing the foregoing problems.

The present invention, in an aspect thereof, has an object to provide an optical sensor capable of stable measurement regardless of ambient brightness.

### Solution to the Problems

An optical sensor in an aspect includes: a light-emitting element configured to project light that changes with time; a light-receiving element including a pn junction and configured to directly or indirectly receive the light projected by the light-emitting element; a measuring section configured to measure an electric current generated based on an amount of the light received by the light-receiving element; and a bias application section configured to apply a bias to the light-receiving element, wherein the bias application section, before measuring the electric current generated based on the amount of the light received, applies the bias to the light-receiving element to cause either a forward current that flows when the light-receiving element is turned ON or a breakdown current that flows when the pn junction breaks down to flow through the pn junction.

### BRIEF DESCRIPTION OF THE DRAWINGS

FIG. 1 is a schematic illustration of an optical sensor in accordance with Embodiment 1 of the present invention.

FIG. 2 is a circuit diagram of the optical sensor in accordance with Embodiment 1 of the present invention.

FIG. 3 is a timing chart showing various signals in the optical sensor in accordance with Embodiment 1 of the present invention.

FIG. 4A is a circuit diagram of the optical sensor in accordance with Embodiment 1 of the present invention when the optical sensor is in a standby operation.

FIG. 4B is a graph representing the current-voltage characteristics of a photodiode included in the optical sensor in accordance with Embodiment 1 of the present invention.

FIG. 5A is a circuit diagram of the optical sensor in accordance with Embodiment 1 of the present invention when the optical sensor is in a proximity operation.

FIG. 5B is a graph representing the outputs of an integration circuit and a counter circuit when the optical sensor in accordance with Embodiment 1 of the present invention is in a proximity operation.

FIG. 6A is a graph representing a relationship between the number of measurements and a count when an optical sensor in accordance with a comparative example is in a proximity operation.

FIG. 6B is a graph representing a relationship between the number of measurements and a count when the optical sensor in accordance with Embodiment 1 of the present invention is in a proximity operation.

FIG. 7 is a cross-sectional view of the photodiode in accordance with Embodiment 1 of the present invention.

FIG. 8 is a cross-sectional view of the photodiode in accordance with Embodiment 1 of the present invention.

FIG. 9 is a cross-sectional view of the photodiode in accordance with Embodiment 1 of the present invention.

FIG. 10 is a set of cross-sectional views of the photodiode in accordance with Embodiment 1 of the present invention.

FIG. 11 is a circuit diagram of an optical sensor in accordance with Embodiment 2 of the present invention.

FIG. 12A is a circuit diagram of the optical sensor in accordance with Embodiment 2 of the present invention when the optical sensor is in a standby operation.

FIG. 12B is a circuit diagram of the optical sensor in accordance with Embodiment 2 of the present invention when the optical sensor is in a proximity operation.

FIG. 13 is a circuit diagram of an optical sensor system in accordance with Embodiment 3 of the present invention.

### DETAILED DESCRIPTION OF THE INVENTION

The following will describe embodiments of the present invention with reference to drawings. Note that identical and equivalent elements in the drawings are denoted by the same reference numerals, and description thereof is not repeated.

### Embodiment 1

A description is now given of an optical sensor in accordance with Embodiment 1 of this invention. The following description will describe proximity sensors as exemplary optical sensors.

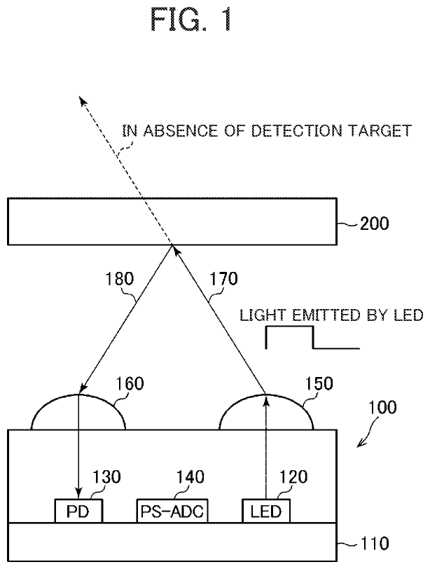

A description is given first of a structure of a proximity sensor in accordance with the present embodiment. FIG. 1 is a schematic illustration of a structure of the proximity sensor in accordance with the present embodiment, showing only major components of the proximity sensor.

As shown in FIG. 1, a proximity sensor (optical sensor) 100 includes a substrate 110, a light-emitting diode (light-emitting element) 120, a photodiode (light-receiving element) 130, a measuring section 140, a projection lens 150, and a light-receiving lens 160. The substrate 110 is, for example, a PCB (printed circuit board) substrate and carries thereon the light-emitting diode 120, the photodiode 130, and the measuring section 140. The light-emitting diode 120, driven by a control section (not shown), outputs light to project the light onto a detection target 200. Note that although this example discusses an example where the light-emitting diode 120 is used, the light-emitting element may be a laser diode and is not necessarily limited to a light-emitting diode so long as the light-emitting element is capable of projecting light. More specifically, the light outputted by the light-emitting diode 120 is projected onto the detection target 200 by the projection lens 150 (light 170). The reflected light 180 off the detection target 200 is converged by the light-receiving lens 160 and is incident on the photodiode 130. The photodiode 130 receives the reflected light 180 off the detection target 200 and converts the received light to an electric current. The measuring section 140, for example, detects the detection target 200 and/or measures a distance to the detection target 200, by means of the electric current flow in the photodiode 130. Note that the measuring section 140 is, for example, a proximity-sensor (ps)-adc (analog-to-digital converter). APS-ADC is an analog/digital converter circuit for converting an input current from the photodiode 130, which has an analog value, to a digital value. Analog/digital conversion employs, for example, an integration circuit. Needless to say, the measuring section 140 is not necessarily a PS-ADC and by no means limited so long as the measuring section 140 has such a structure as to be capable of, for example, detecting the detection target 200 and measuring a distance on the basis of an input current from the photodiode 130. Additionally, the photodiode 130 and the PS-ADC 140 are now often integrated into a single semiconductor chip, but may be either integrated into a single semiconductor chip or provided in different semiconductor chips. Either structure is similarly effective in achieving the effects described below.

In this structure, when the detection target 200 is located close to the proximity sensor 100, the intensity of the reflected light 180 received by the photodiode 130 is high, and the current flow in the photodiode 130 is large. In contrast, when the detection target 200 is located away from the proximity sensor 100, the intensity of the reflected light 180 received by the photodiode 130 is low, and the current flow in the photodiode 130 is small. In other words, it becomes possible to determine whether or not the detection target 200 is located within a predetermined distance of the proximity sensor 100, by detecting the amount of current flow in the photodiode 130.

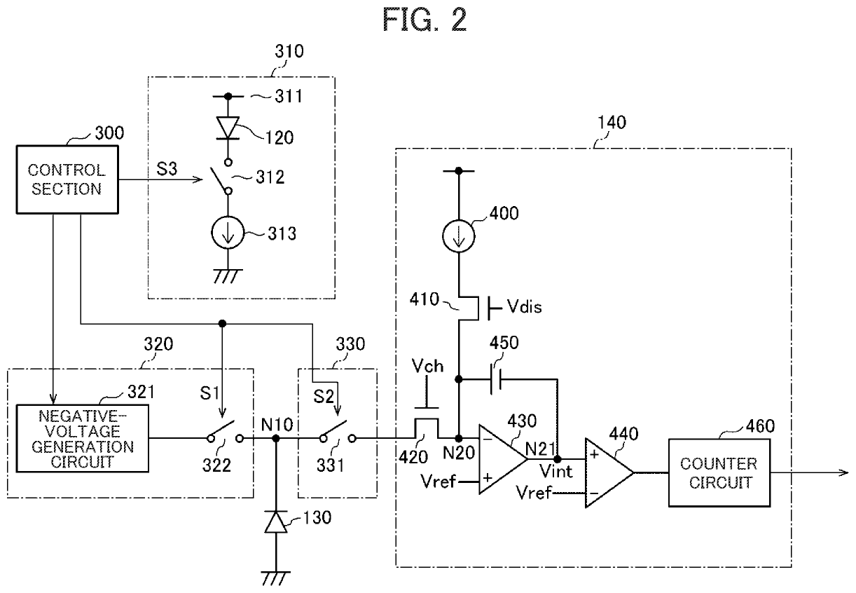

FIG. 2 is a detailed circuit diagram of the proximity sensor 100 shown in FIG. 1. As shown in FIG. 2, the proximity sensor 100 roughly includes a control section 300, a light-emitting section 310, the photodiode 130, the measuring section 140, a bias application section 320, and a switch section 330.

The light-emitting section 310 includes a power supply 311, a switch element 312, a current source 313, and the light-emitting diode 120 shown in FIG. 1. The switch element 312 is controlled through a signal S3 fed from the control section 300 and connects the cathode of the light-emitting diode 120 to the current source 313. Additionally, the anode of the light-emitting diode 120 is connected to the power supply 311. Then, as the signal S3 changes to, for example, the “H” level, and the switch element 312 hence goes ON, the light-emitting diode 120 is fed with a current, thereby projecting light toward the detection target 200. The light-emitting diode 120 is toggled between the ON state (lighted out) and the Off state (lighted up) by the switch element 312 in this manner. In other words, the light-emitting diode 120 projects temporally changing light. Additionally, the light-emitting diode 120 may perform an intermittent operation to reduce the current consumption of the proximity sensor 100.

The photodiode (light-receiving element) 130 is as described with reference to FIG. 1. When the reflected light 180 from the detection target 200 is incident on the pn junction of the photodiode 130, the photodiode 130 conducts a current. The photodiode 130 is grounded, for example, at the anode thereof and connected to a node N10 at the cathode thereof.

The bias application section 320 applies a bias to the photodiode 130. Specifically, by applying a bias to the photodiode 130 before the light-emitting diode 120 projects light to measure the distance to the detection target 200, a forward current that flows when the photodiode 130 is turned ON is caused to flow through the pn junction. More specifically, the bias application section 320 includes a negative-voltage generation circuit 321 and a switch element 322. The negative-voltage generation circuit 321 generates a negative voltage under the control of the control section 300. This negative voltage is a voltage for, in a standby operation (detailed later), being applied to the photodiode 130 to cause a forward current that flows when the photodiode is turned ON to flow in the pn junction of the photodiode 130. This operation will be described later in more detail. The switch element 322 is controlled through a signal S1 fed from the control section 300 and connects the negative-voltage generation circuit 321 to the node N10. Then, as the signal S1 changes to, for example, the “H” level, and the switch element 322 hence goes ON, the negative voltage generated by the negative-voltage generation circuit 321 is applied to the node N10, in other words, to the cathode of the photodiode 130. In contrast, as the signal S1 changes to, for example, the “L” level, and the switch element 322 hence goes OFF, the negative-voltage generation circuit 321 is electrically disconnected from the node N10.

The switch section 330 includes a switch element 331. The switch element 331 is controlled through a signal S2 fed from the control section 300 and connects the measuring section 140 to the node N10, in other words, to the light-emitting diode 120. Then, as the signal S2 changes to, for example, the “H” level, and the switch element 331 hence goes ON, the photodiode 130 is electrically connected to the measuring section 140, and as the signal S2 changes to, for example, the “L” level, and the switch element 331 hence goes OFF, the photodiode 130 is electrically disconnected from the measuring section 140.

The measuring section 140, as described above, is, for example, a PS-ADC and measures the distance to the detection target 200 on the basis of the light received by the photodiode 130. The measuring section 140 includes a current source 400, n channel MOS transistors 410, 420, an operational amplifier (amplifier) 430, a comparator (comparator) 440, a capacitive element (capacitor) 450, and a counter circuit 460. The MOS transistor 410 is fed with a current from the current source 400 at the drain thereof, connected to a node N20 (the inverting input terminal (−) of the operational amplifier 430) at the source thereof, and fed with a voltage Vdis at the gate thereof. The MOS transistor 420 is connected to the switch element 331 at the source thereof, connected to the node N20, in other words, to the inverting input terminal of the operational amplifier 430, at the drain thereof, and fed with a voltage Vch at the gate thereof. The operational amplifier 430 is connected to the node N20 at the inverting input terminal (−) thereof and fed with a reference voltage Vref at the non-inverting input terminal (+) thereof. The operational amplifier 430 then outputs an amplified differential signal from the node N20 and the reference voltage Vref as a voltage Vint to a node N21. The capacitive element 450 is connected to the node N20 at one of the electrodes thereof to the node N21 at the other electrode thereof. The comparator 440 is connected to the node N21 at the non-inverting input terminal (+) thereof and fed with the reference voltage Vref at the inverting input terminal (−) thereof. The comparator 440 then outputs a result of comparison of the node N21 with the reference voltage Vref. The counter circuit 460 performs a counting operation on the basis of an output of the comparator 440 and outputs a result of the counting operation. As described here, the measuring section 140 includes an integration circuit composed primarily of the operational amplifier 430 and the capacitive element 450, and the count by the counter circuit 460 varies on the basis of the quantity of charge generated by the photodiode 130.

The control section 300 controls the entire operation of the proximity sensor 100 structured as in the earlier description. The control section 300 controls, for example, the signals S1, S2, S3, the voltages Vdis, Vch, and the operation timings of, for example, the negative-voltage generation circuit 321.

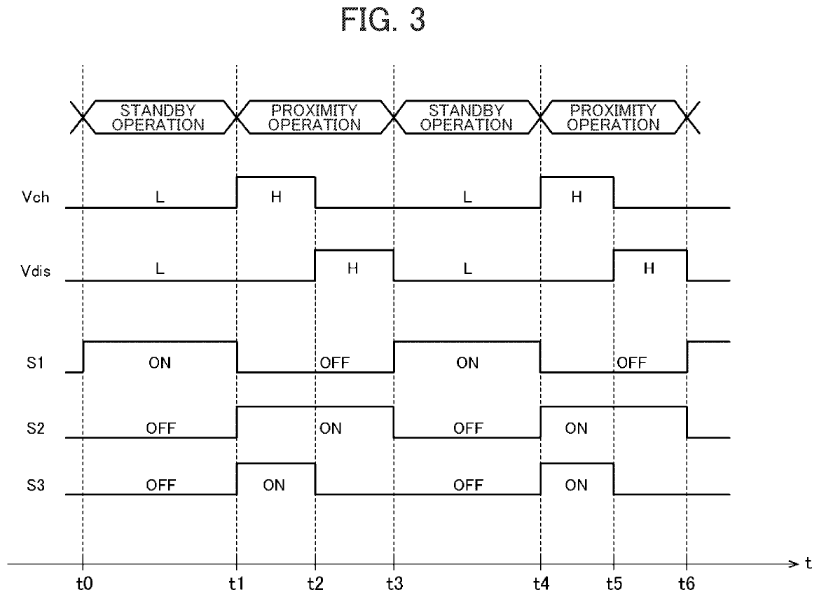

A description is given next of an operation of the proximity sensor 100 in accordance with the present embodiment. FIG. 3 is a timing chart depicting the operation phases of the proximity sensor 100, the voltages Vch, Vdis, and the signals S1, S2, S3.

As shown in FIG. 3, the proximity sensor 100 repeats, in accordance with instructions from the control section 300, a standby operation (second operation) where the distance to the detection target 200 is not measured and a proximity operation (first operation) where the distance to the detection target 200 is measured. A standby operation is performed before a proximity operation. A description is given first of the standby operation. The standby operation, performed before a proximity operation, is an operation of rendering the bright environment and the dark environment have approximately the same lattice defect state (detailed later), by applying a bias to the photodiode 130 from the bias application section 320 to cause a current flow in the pn junction of the photodiode 130. Note that in the example of FIG. 3, a standby operation is described as being performed every time a proximity operation is performed for a simple description. Alternatively, two or more proximity operations may be successively performed.

Referring to FIG. 3, during the standby operation periods (time t0 to t1 and t3 to t4), the control section 300 sets the voltages Vch and Vdis to the “L” level, thereby turning OFF the MOS transistors 420 and 410, to deactivate the measuring section 140. Additionally, the control section 300 sets the signal S1 to the “H” level and the signals S2 and S3 to the “L” level, to electrically connect the bias application section 320 to the photodiode 130 and electrically disconnect the photodiode 130 from the measuring section 140. In addition, the switch element 312 is turned OFF in the light-emitting section 310, to stop the projection of light by the light-emitting diode 120.

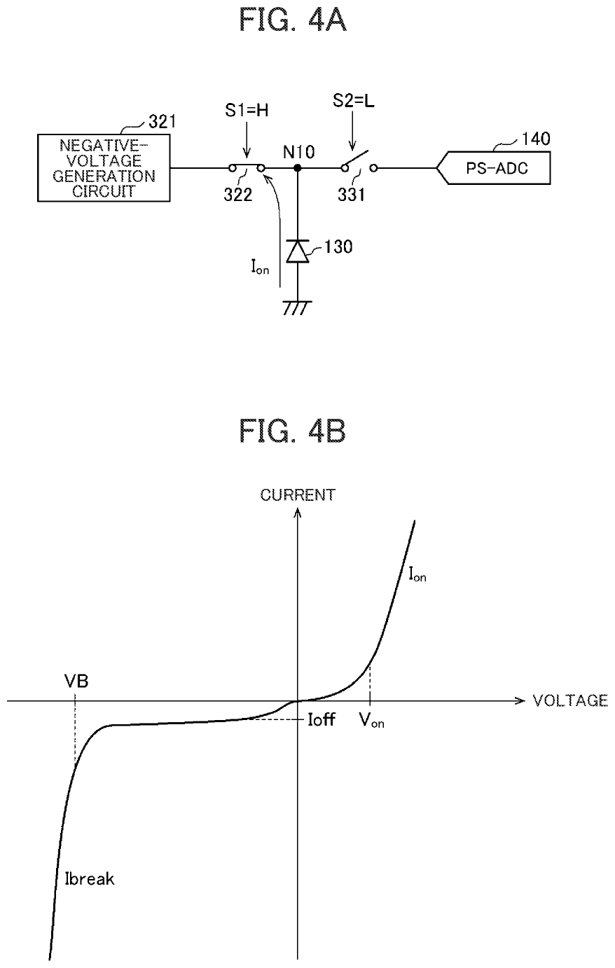

FIG. 4A is a schematic circuit diagram showing how the bias application section 320, the photodiode 130, the switch section 330, and the measuring section 140 are connected in the standby operation. As described earlier, as the switch element 322 is turned ON, and the switch element 331 is turned OFF, the photodiode 130 is connected to the negative-voltage generation circuit 321 and disconnected from the measuring section 140. On the basis of an instruction from the control section 300, the negative-voltage generation circuit 321 then outputs a negative voltage for application to the cathode of the photodiode. This negative voltage outputted by the negative-voltage generation circuit 321 is a forward bias (e.g., −0.7 V) for the photodiode 130 the anode of which is grounded. As a result, the photodiode 130 is turned ON, thereby conducting an ON current ION.

FIG. 4B is a graph representing the current-voltage characteristics of the photodiode 130. As shown in FIG. 4B, as a forward (positive) voltage is applied to the photodiode, the ON current ION starts flowing from the anode to the cathode when a forward bias VON is applied. The ON current ION is a forward current that rapidly increases with a voltage. In the standby operation, the negative-voltage generation circuit 321 applies a negative voltage to the cathode of the photodiode 130. As a result, a forward bias is applied to the pn junction of the photodiode 130 because the anode of the photodiode 130 is grounded. As a result, a forward current ION shown in FIG. 4B flows in the pn junction of the photodiode 130. The photodiode 130 conducts an electric current in the standby operation for the purpose of trapping electrons in lattice defects in the photodiode 130 so as to enable a stable proximity operation in both dark and bright environments. This will be described later in more detail.

Note that as a characteristic of the photodiode 130, under a reverse bias having a voltage value the absolute value of which exceeds a predetermined value (breakdown voltage VB), the pn junction breaks down, causing a breakdown current Ibreak to flow. The breakdown current Ibreak is a reverse current that flows from the anode to the cathode and that, similarly to the forward current, rapidly increases with a voltage. In addition, a small amount of reverse leak current Toff flows during periods even when the reverse bias has a voltage value the absolute value of which is lower than the breakdown voltage VB, and the photodiode is hence turned OFF. In the aforementioned standby operation, the current ION that flows in the photodiode has an absolute value greater than the absolute value of the leak current Ioff and greater than the absolute value of the dark current that flows when no light is incident on the photodiode 130.

A description is given next of the proximity operation. As shown in FIG. 3, during the proximity operation periods (time t1 to t3, t4 to t6), the control section 300, first, during a period from time t1 to t2 (and from t4 to t5), sets the voltage Vch to the “H” level, thereby turning ON the MOS transistor 420, and sets the voltage Vdis to the “L” level, thereby turning OFF the MOS transistor 410. Subsequently, the control section 300, during a period from time t2 to t3 (and from t5 to t6), sets the voltage Vch to the “L” level, thereby turning OFF the MOS transistor 420, and sets the voltage Vdis to the “H” level, thereby turning ON the MOS transistor 410. Additionally, the control section 300 sets the signal S1 to the “L” level and the signal S2 to the “H” level, thereby electrically disconnecting the bias application section 320 from the measuring section 140 and electrically connecting the photodiode 130 to the measuring section 140 during the proximity operation period. Additionally, the control section 300, during a period from time t1 to t2 (and from t4 to t5), sets the signal S3 to the “H” level, thereby causing the light-emitting diode 120 to project light onto the detection target 200.

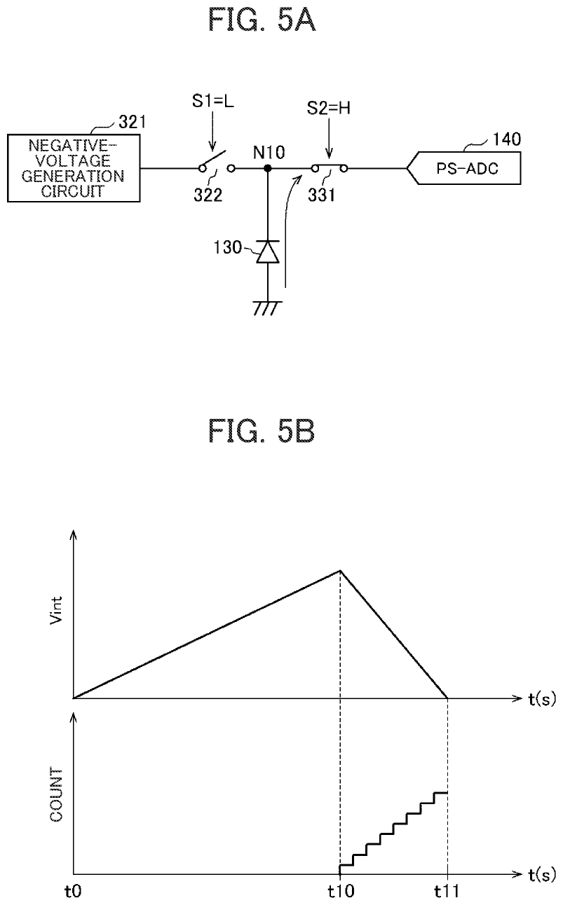

FIG. 5A is a schematic circuit diagram showing how the bias application section 320, the photodiode 130, the switch section 330, and the measuring section 140 are connected in the proximity operation. As described earlier, as the switch element 322 is turned OFF, and the switch element 331 is turned ON, the photodiode 130 is connected to the measuring section 140 and disconnected from the negative-voltage generation circuit 321. In addition, at time t1 (and at time t4), the light-emitting diode 120 projects light onto the detection target 200, and the light reflected off the detection target 200 is incident on the photodiode 130, thereby causing the photodiode 130 to conduct. Then, during a period from time t1 to t2 (and from t4 to t5), the MOS transistor 420 is turned ON, thereby causing the capacitive element 450 to be charged with an electric charge in accordance with the current flow in the photodiode 130. Thereafter, as the light-emitting diode 120 stops projecting light at time t2 (and at time t5), the MOS transistor 410 is turned ON during a period from time t2 to t3 (and from t5 to t6), causing the capacitive element 450 to discharge the electric charge stored therein via the current source 400. In this manner, the light-emitting diode 120 toggles between the ON state and the OFF state, in other words, projects temporally changing light onto the detection target 200.

A description is given of an operation in the proximity operation described above, with reference to FIG. 5B. FIG. 5B is a graph representing the voltage Vint outputted by the operational amplifier 430 and the count by the counter circuit 460. As shown in FIG. 5B, during a period when the MOS transistor 420 is turned ON, thereby causing the capacitive element 450 to be charged with an electric charge (from time t0 to t10), the voltage Vint rises. Then, as the MOS transistor 420 is turned OFF, and the MOS transistor 410 is turned ON, thereby causing the capacitive element 450 to start discharging the electric charge stored therein, the voltage Vint falls. Note that the voltage Vref fed to the operational amplifier 430 is, for example, 0 V. The counter circuit 460 then counts the period from time t10 to time t11 when the voltage Vint changes to 0 V, and this count is outputted as a value correlated to the distance to the detection target 200. In this manner, the capacitive element 450 is charged by the current flow in the photodiode 130, the counter circuit 460 counts the time until this electric charge is discharged, and the time the capacitive element 450 takes to completely discharge, in other words, the count by the counter circuit 460, is outputted as a digital value correlated to the distance to the detection target 200. In this manner, the measuring section 140 measures the current generated on the basis of the amount of the light received by the photodiode 130 and determines the distance to the detection target 200 on the basis of the amount of this current.

As described above, the proximity sensor in accordance with the present embodiment enables stable measurement regardless of ambient brightness. This effect is discussed in the following.

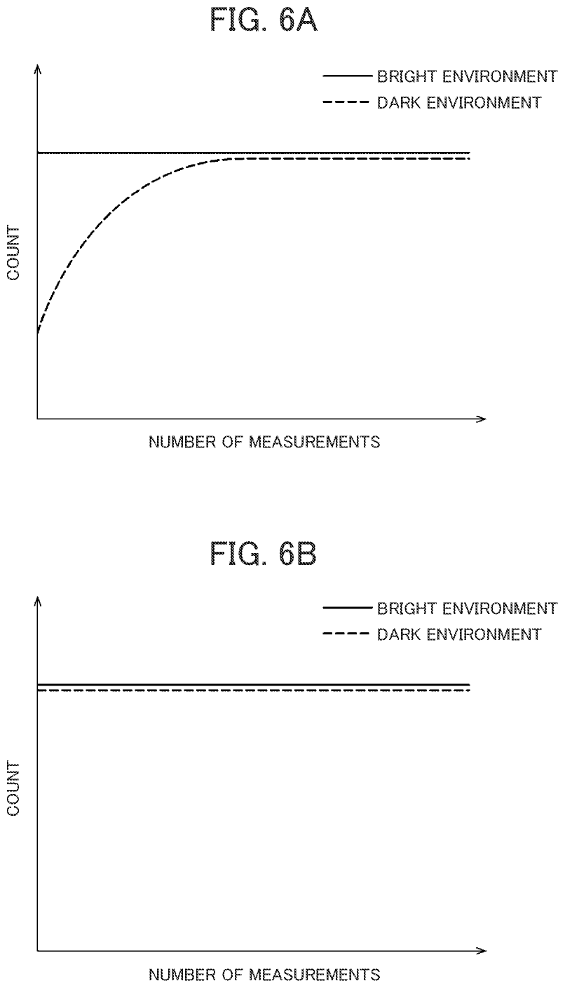

The inventors of the present invention have found an issue that when measurement is done in a bright environment and in a dark environment, it takes time until stable measurement becomes possible in a dark environment. FIG. 6A is a graph representing a relationship between the number of measurements and a count for the proximity sensor in accordance with a comparative example of the present embodiment. The present comparative example shows measurements in a proximity operation when the detection target 200 is present when the standby operation described in the foregoing embodiment is not performed. In the bright environment, the graph indicates detection of a count of, for example, approximately 900 from the first measurement. The count stays substantially unchanged throughout the subsequent measurements. In contrast, in the dark environment, the count is, for example, approximately 600 in the first measurement and gradually increases throughout the subsequent measurements, reaching, for example, a result equivalent to the bright environment in the approximately 25-th measurement. As described here, there are cases in the dark environment where accurate measurements are not available before multiple measurements.

FIG. 6B is a graph representing a relationship between the number of measurements and a count for the proximity sensor in accordance with the present embodiment, showing results of the measurement conducted under the same conditions as FIG. 6A. As shown in FIG. 6B, in the present embodiment, the count in the dark environment is equivalent to the count in the bright environment in the first measurement.

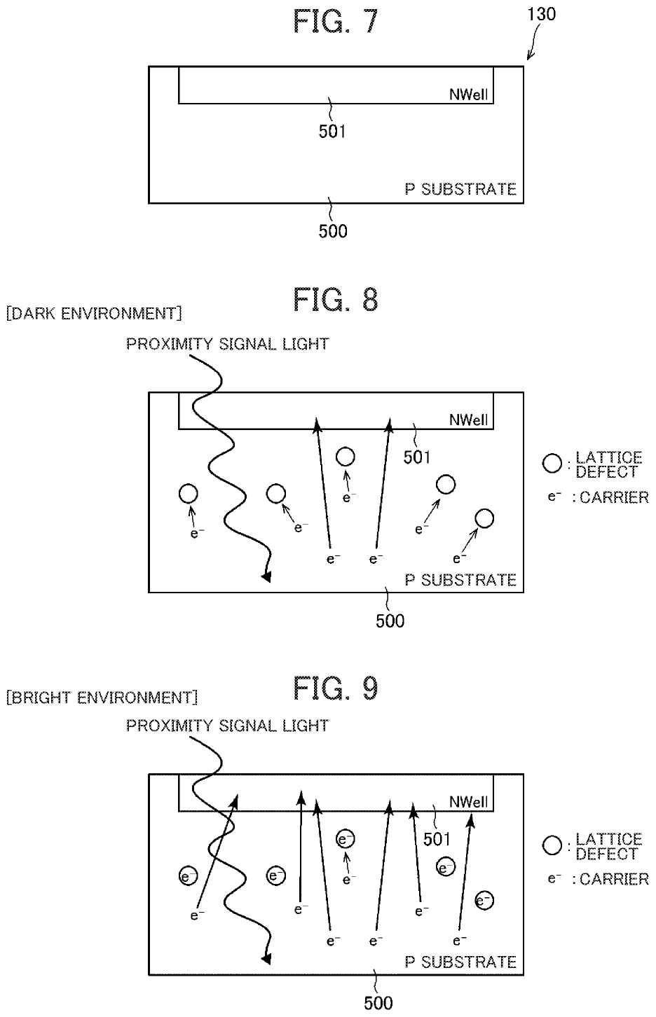

The inventors of the present invention have investigated the phenomenon of inaccurate measurement results in initial measurements in the dark environment as shown in FIG. 6A as follows. FIG. 7 is a cross-sectional view of the photodiode 130. As shown in FIG. 7, the photodiode 130 is formed by, for example, providing a n-type well 501 on a p-type silicon substrate 500. The silicon substrate 500 excites carriers (electrons) under light. These electrons move from the p-type substrate 500 to the n-type well 501 where the energy level is lower, thereby producing an electric current flow in the photodiode 130. It is also known that the silicon substrate 500 has some lattice defects. Accordingly, as shown in the cross-sectional view of the photodiode 130 in accordance with a comparative example in FIG. 8, some of the carriers generated by proximity signal light (light reflected off the detection target 200) in a dark environment would be trapped (recombined) in the lattice defects, so that not all the carriers can be outputted as a signal component.

In contrast, as shown in the cross-sectional view of the photodiode 130 in FIG. 9, carriers are always generated and trapped in the lattice defects in a bright environment. Therefore, almost all the carriers generated by proximity signal light would be outputted as a signal component without being trapped in the lattice defects.

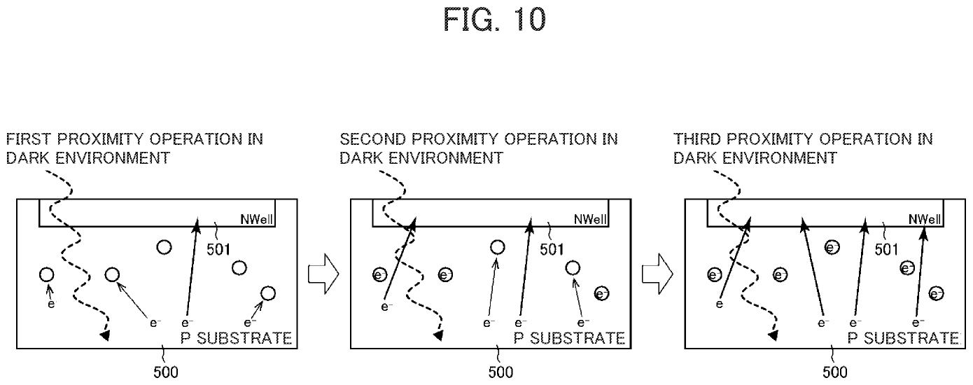

A description is given next of the mechanism by which the proximity measurement results increase when proximity operations are performed continuously from a dark environment. This is presumably the state of the photodiode 130 changing to the state in a bright environment by performing the continuous proximity operations from a dark environment. FIG. 10 is a set of cross-sectional views of the photodiode 130 in accordance with a comparative example, showing changes in the state of the photodiode 130 when proximity operations are performed continuously from a dark environment. As shown in FIG. 10, there would be a maximum number of lattice defects in a dark environment, and if proximity operations are performed under such conditions, the carriers generated by proximity signal light could mostly be outputted from the photodiode as a signal component, but in the presence of lattice defects, would likely be trapped (recombined) in the lattice defects and end up not being outputted as a signal. The lattice defects would be mostly recombined with carriers in the repeatedly performed proximity operations and eventually approach the lattice state of a bright environment.

On the basis of these results of investigation, the present embodiment is capable of solving the current problem (it takes a long time to obtain stable proximity measurement results in a dark environment) by creating the same lattice defect state before the proximity operation in dark and bright environments. Specifically, the lattice defects can be reduced in the silicon substrate 500 by applying voltage to the photodiode 130 and thereby producing an electric current flow in a standby operation. In other words, the bias application section 320 applies a bias (negative voltage in this example) to the photodiode (light-receiving element) 130 before the operation of projecting light from a light-emitting element to measure the distance to a detection target (proximity operation). Hence, the forward current ION, which flows when the photodiode 130 is turned ON, is produced in the pn junction of the photodiode. In other words, electrons are injected to the pn junction of the photodiode 130. Thus, electrons are trapped in the lattice defects in the silicon substrate 500. In other words, the number of the carriers trapped in the defect level is larger after the forward current is produced in the pn junction of the photodiode 130 than before the forward current is produced in the pn junction. As a result of this, an equivalent lattice state to a bright environment can be obtained even in a dark environment, by causing the lattice defects of the photodiode 130 to trap electrons in advance before a proximity operation is performed. Thus, almost all the carriers generated by reflected light can be outputted as a signal component immediately after the start of the measurement even in a dark environment. As described here, the distance to the detection target 200 can be measured under practically the same conditions in both dark and bright environments, by applying voltage to the photodiode 130 and thereby producing an electric current flow before a proximity operation. Therefore, stable measurement becomes possible regardless of ambient brightness, which successfully addresses the current problem.

Note that it is also known that diodes have the property of emitting light, albeit weakly, when an electric current flows therethrough. Carriers can possibly be generated in the photodiode by the weak light emitted by none other than the photodiode, in which case the difference of the lattice state in the silicon substrate 500 between bright and dark environments can still be reduced by applying a bias to the photodiode 130.

### Embodiment 2

Next, an optical sensor in accordance with Embodiment 2 will be described. In the present embodiment, the bias application section 320 described in Embodiment 1 above is provided by forming a bipolar transistor instead of the negative-voltage generation circuit 321. The following description will focus on differences from Embodiment 1.

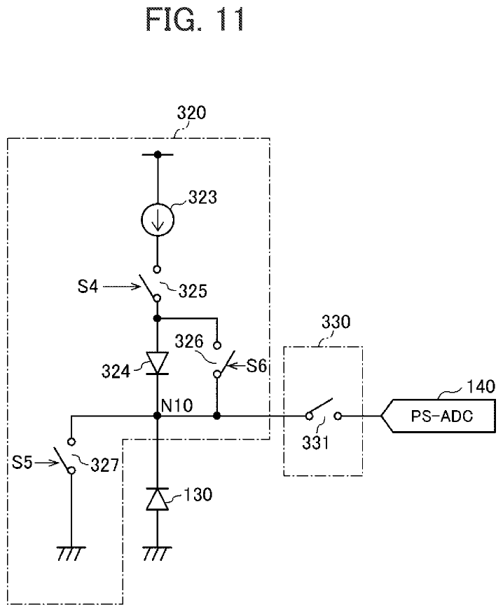

FIG. 11 is a circuit diagram of the bias application section 320, the photodiode 130, the switch section 330, and the measuring section 140 in the proximity sensor 100 in accordance with the present embodiment. As shown in FIG. 11, the bias application section 320 in accordance with the present embodiment includes a current source 323, a diode 324, and switch elements 325, 326, 327. The current source 323 is connected to the anode of the diode 324 via the switch element 325. The switch element 325 is controlled through, for example, a signal S4 fed from the control section 300 and turned ON when the signal S4 changes to, for example, the “H” level. The diode 324 is connected, at the cathode thereof, to the node N10, in other words, the cathode of the photodiode 130. Therefore, the diode 324 and the photodiode 130 function as a pnp bipolar transistor with the cathodes of the diode 324 and the photodiode 130 corresponding to the base electrode. The switch element 326 connects the anode of the diode 324 to the node N10. The switch element 326 is controlled through, for example, a signal S6 fed from the control section 300 and turned ON when the signal S6 changes to, for example, the “H” level. The switch element 327 connects the node N10, in other words, the connecting node where the cathode of the diode 324 connects to the cathode of the photodiode 130, to, for example, a grounding node (first node). The switch element 327 is controlled through, for example, a signal S5 fed from the control section 300 and turned ON when the signal S5 changes to, for example, the “H” level.

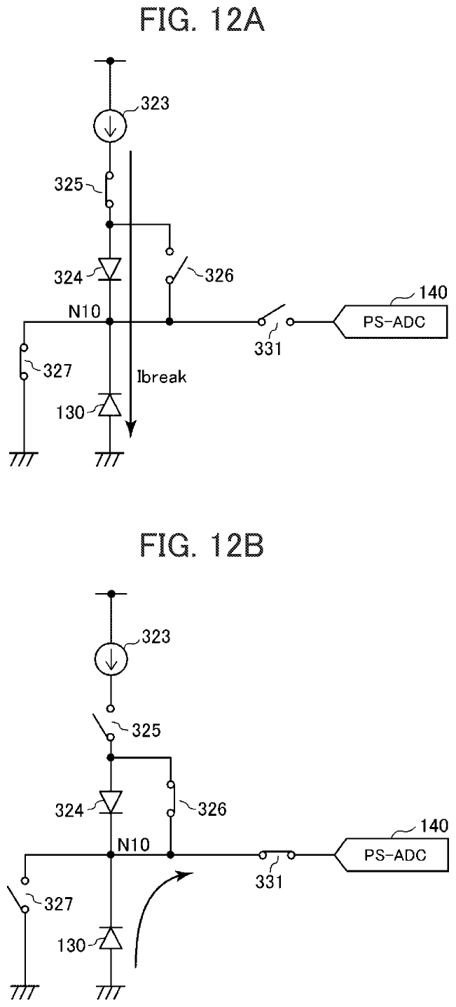

FIG. 12A shows an operation of the bias application section 320 in a standby operation. As shown in FIG. 12A, in a standby operation, the control section 300 sets the signals S4 and S5 to the “H” level and the signal S6 to the “L” level. Hence, the switch elements 325 and 327 are turned ON. Accordingly, the potential of the node N10, in other words, the base potential of the bipolar transistor formed by the diode 324 the photodiode 130, changes to 0 V, which turns ON this bipolar transistor. Hence, an electric current flows in the photodiode 130 from the current source 323 via the diode 324 and the node N10. At this time, a reverse bias is applied to the pn junction of the photodiode 130, and this pn junction breaks down, causing the breakdown current Ibreak described with reference to FIG. 3B to flow. The breakdown current Ibreak has an absolute value greater than the absolute value of the leak current Ioff similarly to the current ION described in Embodiment 1 and greater also than the absolute value of the dark current that flows when no light is incident on the photodiode 130. Note that an example has been so far described where the first node at which the base of the aforementioned bipolar transistor is connected by the switch element 327 is grounded (to 0 V), but the first node is not necessarily grounded and may have such an electrical potential that a breakdown current can flow in the photodiode 130 when the bipolar transistor is turned ON.

FIG. 12B shows an operation of the bias application section 320 in a proximity operation. As shown in FIG. 12B, in a proximity operation, the control section 300 sets the signals S4 and S5 to the “L” level and the signal S6 to the “H” level. Hence, the switch elements 325 and 327 are turned OFF, and the switch element 326 is turned ON. Accordingly, the anode and cathode of the diode 324 have the same electrical potential, electrically disconnecting the cathodes of the diode 324 and the photodiode 130 from the first node. Therefore, the bipolar transistor formed by the diode 324 the photodiode 130 is turned OFF, and no electric current flows from the current source 323 to the photodiode 130. Then, the switch element 331 is turned ON, causing the capacitive element 450 in the measuring section 140 to be charged with an electric charge based on the electric current generated by the light reflected off the detection target 200.

As described above, the bias application section 320 may be provided by forming a bipolar transistor. Embodiment 1 describes the negative-voltage generation circuit 321 being used as the bias application section 320. However, it may be difficult to use a negative voltage circuit, depending on, for example, the employed semiconductor process and the allowable chip size. If so, effects that are similar to Embodiment 1 can be achieved by applying a reverse bias to the photodiode 130 and thereby producing a breakdown current flow. However, a sufficient electric current flow may not be produced when an ordinary power supply voltage is used (e.g., approximately 1.8 to 3.6 V). In such cases, this trouble can be addressed by forming a pnp bipolar transistor by connecting the cathode of the photodiode 130 to the cathode of another diode (photodiode) as in the present embodiment. Hence, even when an ordinary power supply voltage is used, it is possible produce an electric current flow in the photodiode 130.

Then, according to the present method, carriers can be injected to the pn junction of the photodiode 130 similarly to Embodiment 1, by producing the breakdown current Ibreak in the photodiode 130. Hence, an equivalent lattice state to a bright environment can be obtained even in a dark environment, by causing the lattice defects of the photodiode 130 to trap carriers in advance before a proximity operation is performed. Thus, almost all the carriers generated by reflected light can be outputted as a signal component immediately after the start of the measurement even in a dark environment.

### Embodiment 3

Next, an optical sensor in accordance with Embodiment 3 will be described. In Embodiments 1 and 2 above, an example is described where the proximity sensor 100 includes the light-emitting element 120. In contrast, the present embodiment relates to a structure where in Embodiments 1 and 2, the proximity sensor 100 includes no light-emitting element, and there are provided a light-emitting element and a light-emitting-element drive circuit outside the proximity sensor 100. The following description will focus on differences from Embodiments 1 and 2.

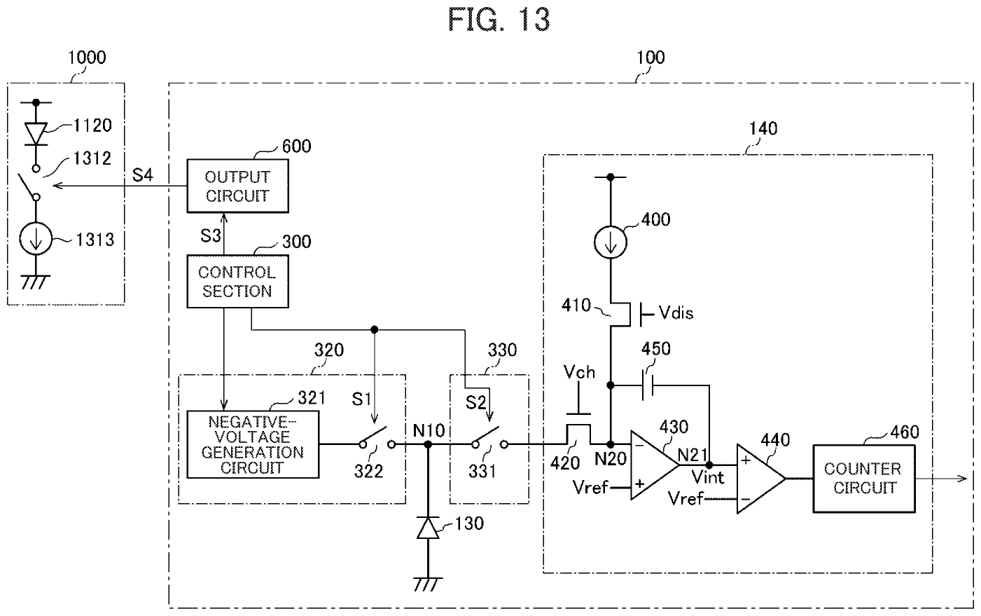

FIG. 13 is a circuit diagram of an optical sensor system in accordance with the present embodiment. As shown in FIG. 13, the optical sensor system includes the proximity sensor 100 and a light-emitting-element drive circuit 1000. The proximity sensor 100 has substantially the same structure as the structure of Embodiments 1 and 2, but differs from the structure shown in FIG. 2 described in Embodiment 1 in that the light-emitting section 310 is omitted and an output circuit 600 is further included. Note that although FIG. 13 shows the negative-voltage generation circuit 321 described in Embodiment 1 being used as the bias application section 320, a bipolar transistor may be formed as shown in FIG. 11 for Embodiment 2. The control section 300 outputs, to the output circuit 600, the signal S3 for driving the light-emitting element at a timing shown in, for example, FIG. 3 describe in Embodiment 1. The output circuit 600 outputs the received signal S3 to the light-emitting-element drive circuit 1000 outside the proximity sensor 100.

The light-emitting-element drive circuit 1000 is an equivalent of the light-emitting section 310 described in Embodiment 1 and has a similar structure to the light-emitting section. As shown in FIG. 13, the light-emitting-element drive circuit 1000 includes a light-emitting diode (light-emitting element) 1120, a switch element 1312, and a current source 1313. In this example, the light-emitting diode 1120 functions similarly to the light-emitting element 120 described in FIG. 1. The switch element 312 is controlled through the signal S4 fed from the output circuit 600 and connects the cathode of the light-emitting diode 1120 to the current source 1313. Additionally, the anode of the light-emitting diode 1120 is connected to a power supply. Then, as the switch element 1312 is turned ON in response to the signal S4, in other words, the signal S3, changing to, for example, the “H” level, the light-emitting diode 1120 is fed with an electric current, thereby projecting light onto the detection target 200. In addition, the light-emitting-element drive circuit 1000 may include a drive circuit (not shown) for controlling the light-emitting diode 1120. Conversely, the switch element 1312 and the current source 1313 may be provided inside the proximity sensor 100, and the light-emitting diode 1120 alone may be provided outside the proximity sensor 100 (none shown).

According to the present embodiment, the proximity sensor 100 and the light-emitting element 1120 are provided independently from each other. Therefore, the present embodiment is particularly useful in applications in which the distance between the light-emitting element 1120 and the light-receiving element 130 should be large.

### Variation Examples and Other Description

As described above, the optical sensors in accordance with Embodiments 1 and 2 enable improving reliability of proximity operations regardless of whether the proximity operation is performed in a dark environment or in a bright environment. Note that the foregoing description presents various embodiments, and these embodiments are not necessarily limited to the foregoing description and may be modified in various manners.

For instance, the foregoing embodiments describe examples where the photodiode 130 is a pn junction diode. Alternatively, the photodiode 130 may be a PIN diode which includes an intrinsic semiconductor layer between a p-type layer and a n-type layer. Additionally, Embodiment 1 describes an example where the negative-voltage generation circuit 321 is used as the bias application section 320. Alternatively, the bias application section 320 may be a positive-voltage generation circuit depending on the electrical potential of the anode of the photodiode 130 and may be any structure capable of applying a forward bias to the photodiode 130. This is similarly true with Embodiment 2 where the base potential of a virtual pnp bipolar transistor is not necessarily limited to 0 V and may be any electrical potential at which the bipolar transistor is turned ON. In addition, the period during which the photodiode 130 conducts an electric current in a standby operation may be controllable by, for example, the control section 300. In addition, the user may be allowed to specify the period of current flow for the control section 300. An example of the period of current flow is, for example, 100 μs, which depends on, for example, the size of the photodiode 130 and the lattice defect conditions. Therefore, a period that is determined to be suitable in a pre-shipment test operation may be specified for the control section 300. Alternatively, the control section 300 may perform a proximity operation test at, for example, when the device to which the proximity sensor is mounted is powered on, and on the basis of results of the test, a suitable period may be specified. These proximity-sensor-mounted devices may be, for example, smartphone and wireless earphones. For example, when the proximity sensor is mounted to a smartphone, the smartphone typical includes a touch panel on the front face thereof. Therefore, when the smartphone receives an incoming telephone call, and the user brings the smartphone close to his/her ear, the proximity sensor may detect the motion to deactivate the touch panel function. In addition, the proximity sensor is typically disposed below the panel of a smartphone or like electronic apparatus. In this situation, the proximity sensor could malfunction as a result of determining the light reflected off the panel of the electronic apparatus as a detection target. These problems are effectively addressed by separating the light-emitting element and the light-receiving element from each other, and the structure described in Embodiment 3 is preferably adopted. Additionally, the problems with wireless earphones may be addressed by the proximity sensor sensing the wireless earphones moving closer to the user' ears and based on this sensing, outputting a sound. In addition, the timing chart described with reference to FIG. 3 is also a mere example. The timings of the voltages Vch, Vdis and the signals S1 to S3 may be varied where suitable so long as the standby operation and the proximity operation are possible. Furthermore, the description discusses an example where the measuring section 140 is a PS-ADC. The measuring section 140 is however not limited in any particular manner so long as the measuring section 140 has a structure enabling computing the distance to the detection target 200 on the basis of the electric current flow in the photodiode 130.

The description has so far discussed some embodiments of the present invention. The present invention is not limited to the embodiments and examples above and may be modified where appropriate. The structures described above may be replaced by a practically identical structure, a structure that achieves the same effect and function, or a structure that achieves the same purpose. In addition, the foregoing embodiments describe proximity sensors as an example of the optical sensor. The present invention however is effective in all semiconductor optical sensors, such as photo interrupters for detecting a detection target and photocouplers for determining whether or not an electric signal is energized, that receive the light projected by a light-emitting element. Furthermore, the foregoing embodiments describe optical sensors as an example. The present invention however is applicable to impurity-containing semiconductor substrates or to any situations where the presence of an impurity in a semiconductor layer poses a problem. In these cases, the present invention can reduce or completely eliminate defect levels by providing the bias application section 320.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An optical sensor comprising:
a light-emitting element configured to project light that changes with time;
a light-receiving element including a pn junction and configured to directly or indirectly receive the light projected by the light-emitting element;
a measuring section configured to measure an electric current generated based on an amount of the light received by the light-receiving element; and
a bias application section configured to apply a bias to the light-receiving element, wherein
the bias application section, before measuring the electric current generated based on the amount of the light received, applies the bias to the light-receiving element to cause either a forward current that flows when the light-receiving element is turned ON or a breakdown current that flows when the pn junction breaks down to flow through the pn junction.

2. An optical sensor comprising:
a light-receiving element including a pn junction and configured to receive light;
a measuring section configured to measure an electric current generated based on an amount of the light received by the light-receiving element;
a bias application section configured to apply a bias to the light-receiving element; and
a control signal output section configured to cause an external light-emitting element to output an optical signal received by the light-receiving element, wherein
the bias application section, before measuring the electric current generated based on the amount of the light received, applies the bias to the light-receiving element to cause either a forward current that flows when the light-receiving element is turned ON or a breakdown current that flows when the pn junction breaks down to flow through the pn junction.

3. The optical sensor according to claim 1, wherein the forward current caused to flow by the bias application section and the breakdown current caused to flow by the bias application section each have an absolute value that is larger than an absolute value of a leak current that flows when the light-receiving element is turned OFF.

4. The optical sensor according to claim 2, wherein the forward current caused to flow by the bias application section and the breakdown current caused to flow by the bias application section each have an absolute value that is larger than an absolute value of a leak current that flows when the light-receiving element is turned OFF.

5. The optical sensor according to claim 1, wherein the forward current caused to flow by the bias application section and the breakdown current caused to flow by the bias application section each have an absolute value that is larger than an absolute value of a dark current of the light-receiving element.

6. The optical sensor according to claim 2, wherein the forward current caused to flow by the bias application section and the breakdown current caused to flow by the bias application section each have an absolute value that is larger than an absolute value of a dark current of the light-receiving element.

7. The optical sensor according to claim 1, wherein
the optical sensor repeats a first operation where the light is projected by the light-emitting element and the electric current generated based on the amount of the light received is measured and a second operation where the electric current generated based on the amount of the light received is not measured, and
the bias application section causes either the forward current or the breakdown current to flow through the pn junction of the light-receiving element in the second operation.

8. The optical sensor according to claim 2, wherein
the optical sensor repeats a first operation where the light is projected by the light-emitting element and the electric current generated based on the amount of the light received is measured and a second operation where the electric current generated based on the amount of the light received is not measured, and
the bias application section causes either the forward current or the breakdown current to flow through the pn junction of the light-receiving element in the second operation.

9. The optical sensor according to claim 1, further comprising a switch section configured either to electrically connect the light-receiving element to the measuring section or to electrically disconnect the light-receiving element from the measuring section, wherein the switch section electrically disconnects the light-receiving element from the measuring section in a period in which either the forward current or the breakdown current is caused to flow through the pn junction of the light-receiving element and electrically connects the light-receiving element to the measuring section in a period in which the light is projected and the electric current generated based on the amount of the light received is measured.

10. The optical sensor according to claim 2, further comprising a switch section configured either to electrically connect the light-receiving element to the measuring section or to electrically disconnect the light-receiving element from the measuring section, wherein the switch section electrically disconnects the light-receiving element from the measuring section in a period in which either the forward current or the breakdown current is caused to flow through the pn junction of the light-receiving element and electrically connects the light-receiving element to the measuring section in a period in which the light is projected and the electric current generated based on the amount of the light received is measured.

11. The optical sensor according to claim 1, wherein
the light-receiving element is a photodiode with a grounded anode,
the bias application section includes a negative-voltage generation circuit, and
the negative-voltage generation circuit applies a negative voltage to a cathode of the photodiode to apply a forward voltage across the pn junction of the photodiode and to hence cause the forward current to flow.

12. The optical sensor according to claim 2, wherein
the light-receiving element is a photodiode with a grounded anode,
the bias application section includes a negative-voltage generation circuit, and
the negative-voltage generation circuit applies a negative voltage to a cathode of the photodiode to apply a forward voltage across the pn junction of the photodiode and to hence cause the forward current to flow.

13. The optical sensor according to claim 1, wherein
the light-receiving element is a photodiode with a grounded anode,
the bias application section further includes:
a diode with a cathode being connected to a cathode of the photodiode;
a current source connected to an anode of the diode; and
a switch section configured either to connect a first node to the photodiode and the cathode of the diode or to disconnect the first node from the photodiode and the cathode of the diode, and
the switch section connects the first node to the photodiode and the cathode of the diode to cause the breakdown current to flow through the pn junction of the photodiode.

14. The optical sensor according to claim 2, wherein
the light-receiving element is a photodiode with a grounded anode,
the bias application section further includes:
a diode with a cathode being connected to a cathode of the photodiode;
a current source connected to an anode of the diode; and
a switch section configured either to connect a first node to the photodiode and the cathode of the diode or to disconnect the first node from the photodiode and the cathode of the diode, and
the switch section connects the first node to the photodiode and the cathode of the diode to cause the breakdown current to flow through the pn junction of the photodiode.

15. The optical sensor according to claim 8, wherein the first node is grounded.

16. The optical sensor according to claim 1, further comprising a control section configured to control a period in which either the forward current or the breakdown current is caused to flow through the pn junction of the light-receiving element.

17. The optical sensor according to claim 2, further comprising a control section configured to control a period in which either the forward current or the breakdown current is caused to flow through the pn junction of the light-receiving element.

18. The optical sensor according to claim 1, wherein more carriers are trapped in a defect level after either the forward current or the breakdown current is caused to flow through the pn junction than before either the forward current or the breakdown current is caused to flow through the pn junction.

19. The optical sensor according to claim 2, wherein more carriers are trapped in a defect level after either the forward current or the breakdown current is caused to flow through the pn junction than before either the forward current or the breakdown current is caused to flow through the pn junction.

20. An optical sensor, provided on a semiconductor substrate containing an impurity, comprising a bias application circuit configured to cause an electric current to flow through the semiconductor substrate to reduce defect levels caused by the impurity.
